(19) United States
(12) Patent Application Publication
(10) Pub. No.: US 2026/0202519 A1
(43) Pub. Date: Jul. 16, 2026

(54) LIGHT-EMITTING UNIT AND OPTICAL SENSOR

(71) Applicant: DENSO CORPORATION, Kariya-city (JP)

(72) Inventors: Yuhei SHIMIZU, Kariya-city (JP); Masato NAKAJIMA, Kariya-city (JP)

(21) Appl. No.: 19/564,695

(22) Filed: Mar. 12, 2026

Related U.S. Application Data
(63) Continuation of application No. PCT/JP2024/029560, filed on Aug. 21, 2024.

(30) Foreign Application Priority Data
Sep. 15, 2023 (JP) 2023-150338

(51) Int. Cl. G01S 7/484; G01S 7/4863

(52) U.S. Cl. CPC G01S 7/484; G01S 7/4863

(57) ABSTRACT

A light-emitting unit is provided in a light-emitting branch path section that branches off between an inductor and a capacitor in a resonant circuit section. The light-emitting unit includes a light-emitting diode that generates illumination light by emitting light, a discharge switching element that is provided in the light-emitting branch path section and switches on and off discharge from the capacitor by switching, a charge switching element that is provided on the inductor side of a branch point of the light-emitting branch path section in the resonant circuit section and switches on and off charging to the capacitor, and a drive circuit section that controls the discharge switching element and the charge switching element by individual on/off driving. The drive circuit section controls the ON period of the charge switching element prior to the ON timing of the discharge switching element.

### CROSS REFERENCE TO RELATED APPLICATIONS

The present application is a continuation application of International Patent Application No. PCT/JP2024/029560 filed on August 21, 2024, which designated the U.S. and claims the benefit of priority from Japanese Patent Application No. 2023-150338 filed in Japan filed on September 15, 2023, the entire disclosure of the above application is incorporated herein by reference.

### TECHNICAL FIELD

The present disclosure relates to a light-emitting technology in an optical sensor that senses a target by receiving light reflected from the target in response to light irradiated onto a sensing area.

### BACKGROUND

In an optical sensor that receives reflected light in response to irradiated light, an irradiated light is provided by emitting light.

### SUMMARY

An object of the present disclosure is to provide a light-emitting unit and an optical sensor that ensure target sensing accuracy.

Hereinafter, a technical solution of the present disclosure for solving the difficulties will be described.

According to a first aspect of the present disclosure,

a light-emitting unit that provides an irradiated light by emitting light in an optical sensor, which senses a target object by receiving, with a light-receiving unit, reflected light from the target object in response to the irradiated light irradiated onto a sensing area, includes:

a resonant circuit unit having an inductor and a capacitor,

a light-emitting branch path section branching from between the inductor and the capacitor in the resonant circuit section,

a light-emitting diode provided in the light-emitting branch path section and generating the irradiated light by emitting light,

a discharge switching element provided in the light-emitting branch path section for switching on and off discharge from the capacitor,

a charge switching element that is provided in the resonant circuit section on an inductor side of a branch point of the light-emitting branch path section and that switches on and off charging of the capacitor, and

a drive circuit section that controls the discharge switching element and the charge switching element by individual on/off driving.

The drive circuit section controls an ON period of the charge switching element prior to an ON timing of the discharge switching element.

According to a second aspect of the present disclosure,

an optical sensor includes the light-emitting unit according to the first aspect and a light-receiving unit that receives reflected light of the irradiated light emitted by the light-emitting unit.

### BRIEF DESCRIPTION OF THE DRAWINGS

FIG. 1 is a cross-sectional view showing a configuration of an optical sensor according to an embodiment;

FIG. 2 is a schematic diagram showing a mechanical configuration of a light-projecting unit according to an embodiment;

FIG. 3 is a schematic diagram showing a mechanical configuration of a light-receiving unit according to an embodiment;

FIG. 4 is a circuit diagram showing the electrical configuration of a light-emitting unit according to an embodiment;

FIG. 5 is a graph showing the light-emitting characteristics of a light-emitting unit according to an embodiment;

FIG. 6 is a graph showing the light-emitting characteristics of a light-emitting unit according to an embodiment; and

FIG. 7 is a graph showing the light-emitting characteristics of a light-emitting unit according to an embodiment.

### DETAILED DESCRIPTION

In an optical sensor that receives reflected light in response to irradiated light, a light-emitting technology is known, in which the irradiated light is provided by emitting light. In the technology, in a resonant circuit having an inductor and a capacitor, charging and discharging of the capacitor are switched by a switching element, and a light-emitting diode emits light in response to the discharge of the capacitor.

However, in the technology, the peak intensity of the irradiated light by the emitting light remains unchanged. Therefore, when the reflected intensity of the irradiated light is high, such as in the case of a nearby target or a highly reflective target, there is a risk that the received light intensity for the reflected light will saturate, resulting in a decrease in sensing accuracy.

Therefore, an object of the present disclosure is to provide a light-emitting unit and an optical sensor that ensure target sensing accuracy.

Hereinafter, a technical solution of the present disclosure for solving the difficulties will be described.

According to a first aspect of the present disclosure,

a light-emitting unit that provides an irradiated light by emitting light in an optical sensor, which senses a target object by receiving, with a light-receiving unit, reflected light from the target object in response to the irradiated light irradiated onto a sensing area, includes:

a resonant circuit unit having an inductor and a capacitor,

a light-emitting branch path section branching from between the inductor and the capacitor in the resonant circuit section,

a light-emitting diode provided in the light-emitting branch path section and generating the irradiated light by emitting light,

a discharge switching element provided in the light-emitting branch path section for switching on and off discharge from the capacitor,

a charge switching element that is provided in the resonant circuit section on an inductor side of the branch point of the light-emitting branch path section and that switches on and off charging of the capacitor, and

a drive circuit section that controls the discharge switching element and the charge switching element by individual on/off driving.

The drive circuit section controls an ON period of the charge switching element prior to an ON timing of the discharge switching element.

According to a second aspect of the present disclosure,

an optical sensor includes the light-emitting unit according to the first aspect and a light-receiving unit that receives reflected light of the irradiated light emitted by the light-emitting unit.

According to the first and second aspects, the light-emitting branch path section that branches off between the inductor and the capacitor in the resonant circuit section is provided with a light-emitting diode that generates irradiated light by emitting light, and a discharge switching element that turns on and off the discharge from the capacitor by switching. Therefore, in particular, a charge switching element that switches on and off the charging of the capacitor is provided on the inductor side of the branch point of the light-emitting branch path section in the resonant circuit section. According to this configuration, even if the intensity of the reflected light relative to the irradiated light becomes saturated, the ON period of the charge switching element prior to the ON timing of the discharge switching element can be shortened, thereby relatively lowering the light-receiving sensitivity. Therefore, by such shortening control, the peak intensity of the irradiated light can be suppressed to a low intensity that matches the received reflected light, thereby ensuring the accuracy of sensing the target.

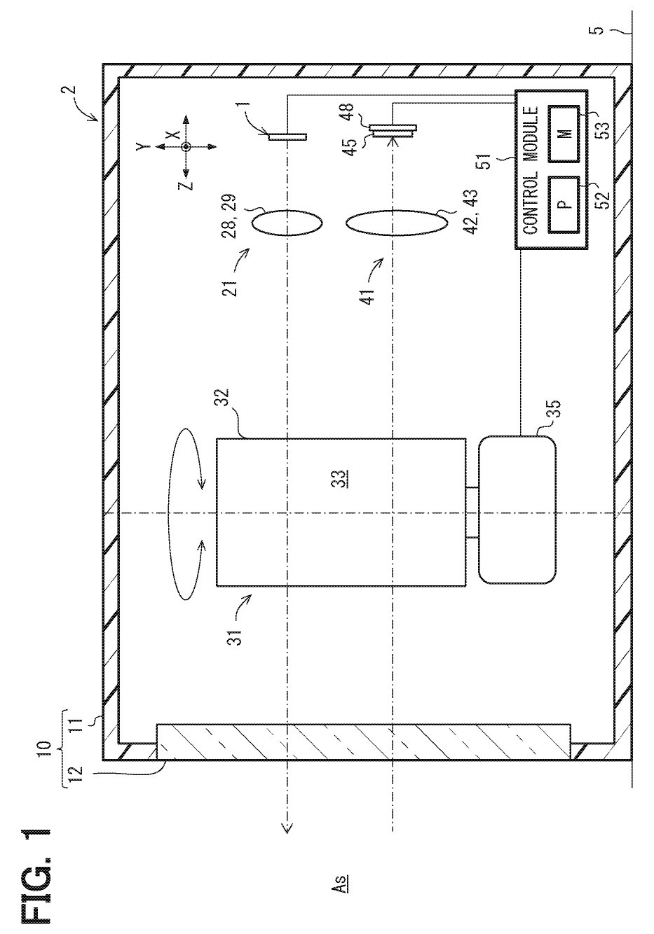

As shown in FIG. 1, one embodiment of the present disclosure relates to an optical sensor 2 including a light-emitting unit 1. The optical sensor 2 is mounted on a vehicle 5. The vehicle 5 is, for example, a moving object such as an automatic vehicle capable of traveling on a traveling road when an occupant is on the vehicle.

The vehicle 5 is capable of traveling automatically constantly or temporarily in an autonomous driving control mode. Here, the autonomous driving control mode may be achieved by autonomous driving control, such as conditional driving automation, altitude driving automation, or full driving automation, in which a system performs all driving tasks when activated. The automated driving control mode may be achieved with an advanced driving assistance control, such as driving assistance or partial driving automation, where the occupant performs some or all driving tasks. The automated driving control mode may be achieved by any one, combination, or switching of autonomous driving control and advanced driving assistance control.

In the following description, unless otherwise noted, front, rear, up, down, left, and right directions are defined with reference to the vehicle 5 on a horizontal plane. The horizontal direction indicates a direction parallel to a horizontal plane serving as a direction reference of the vehicle 5. A vertical direction indicates a direction perpendicular to the horizontal plane serving as the direction reference of the vehicle 5, which is also an up-down direction.

The optical sensor 2 is a so-called LiDAR (Light Detection and Ranging/Laser Imaging Detection and Ranging) for acquiring image data that can be used for driving control of the vehicle 5 including the automated control driving mode. The optical sensor 2 is disposed in at least one of a front portion, left and right side portions, a rear portion, and an upper roof of the vehicle 5.

In the optical sensor 2, a three-dimensional orthogonal coordinate system is defined by three mutually orthogonal axes: an X-axis, a Y-axis, and a Z-axis. Particularly in the present embodiment, the X-axis and the Z-axis are set along different horizontal directions of the vehicle 5, and the Y-axis is set along the vertical direction of the vehicle 5. In FIG. 1, the left side of the dashed dotted line along the Y axis (the side of a light-transmitting panel 12 described later) actually shows a cross section perpendicular to the right side of the dashed dotted line (the side of the modules 21 and 41 described later) given by the three-dimensional orthogonal coordinate system.

The optical sensor 2 emits light toward a sensing area As in the external space of the vehicle 5, the sensing area As being determined by the placement location and field of view angle of the sensor. The optical sensor 2 receives reflected light that is incident when the irradiated light is reflected from the sensing area As. In response to the reception of the reflected light with respect to the irradiated light, the optical sensor 2 senses a target that reflects the light in the sensing area As. In particular, the sensing means that, among a reflection point distance from the optical sensor 2 to the target and a reflection intensity from the target, at least the former is measured.

A typical sensing target object in the optical sensor 2 applied to the vehicle 5 may be at least one of moving objects such as a pedestrian, a cyclist, an animal other than a human, and other vehicles. The typical sensing target object in the optical sensor 2 applied to the vehicle 5 may be at least one type of stationary objects such as a guardrail, a road sign, a structure beside a road, and a fallen object on a road.

The optical sensor 2 includes a casing module 10, a light-projecting module 21, a scanning module 31, a light-receiving module 41, and a control module 51. The casing module 10 includes a housing 11 and a light-transmitting panel 12. The housing 11 is formed in a hollow box shape and is mainly made of a light-shielding member such as metal or synthetic resin. The housing 11 accommodates the light-projecting module 21, the scanning module 31, and the light-receiving module 41 therein. The housing 11 holds a light-transmitting panel 12 formed into a plate shape from a light-transmitting material such as glass or synthetic resin.

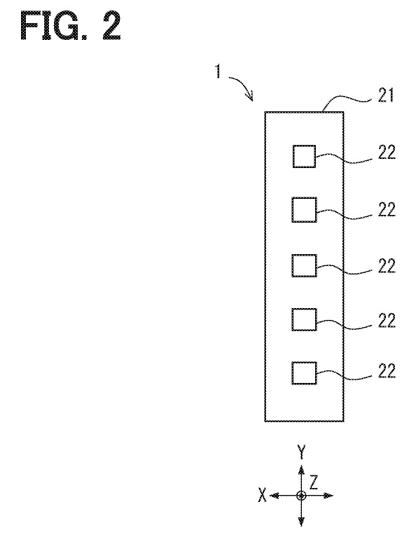

The light-projecting module 21 includes the light-emitting unit 1 and a light-projecting lens system 28. As shown in FIG. 2, the light-emitting unit 1 is constructed by mounting a plurality of light-emitting diodes 22 in an array on a substrate. Each light-emitting diode 22 generates pulsed infrared laser light to be irradiated onto the sensing area As under the control of the control module 51. Each such light-emitting diode 22 is provided as a laser diode, such as an edge emitter laser or a vertical cavity surface emitting laser (VCSEL).

As shown in FIG. 1, the light-projecting lens system 28 projects the irradiated light emitted by the light-emitting unit 1 onto the scanning mirror 32 of the scanning module 31. The light-projecting lens system 28 provides at least one type of optical function among, for example, condensing, collimating, and shaping. The light-projecting lens system 28 forms a projection optical axis along the Z axis. The light-projecting lens system 28 has at least one projecting lens 29 on the projection optical axis, the lens shape of which corresponds to the optical effect to be exhibited. The light-emitting unit 1 is positioned on the projection optical axis of the light-projecting lens system 28. In the light-emitting unit 1, the irradiated light emitted by each light-emitting diode 22 is guided along the light-projecting optical axis of the light-projecting lens system 28.

The scanning module 31 includes a scanning mirror 32 and a scanning motor 35. The scanning mirror 32 is formed into a plate shape by depositing a reflective film on a reflecting surface 33, which is one side of a base material. The scanning mirror 32 is supported by the housing 11 so as to be rotatable around (in other words, in a periphery of) a rotation center line along the Y-axis. The scanning mirror 32 oscillates within a driving range that is limited by the function of a mechanical or electrical stopper.

The scanning mirror 32 is provided in common to the light-projecting module 21 and the light-receiving module 41. The scanning mirror 32 illuminates the sensing area As through the light-transmitting panel 12 by reflecting the irradiated light incident from the light-projecting lens system 28 of the light-projecting module 21 on the reflecting surface 33, which is oriented according to the rotation angle, thereby scanning the area As both temporally and spatially. In particular, in the optical sensor 2, the mechanical scanning of the sensing area As by the irradiated light is substantially limited to scanning in the horizontal direction.

Simultaneously with this scanning, the scanning mirror 32 further reflects the reflected light incident from the sensing area As through the light-transmitting panel 12 toward the light-receiving module 41 by the reflecting surface 33 oriented according to the rotation angle. Here, the speed of the irradiation light and the reflection light are sufficiently large relative to the rotational speed of the scanning mirror 32. As a result, the reflected light of the irradiated light is guided toward the light-receiving module 41 side so as to travel in the opposite direction to the irradiated light by the scanning mirror 32 which has approximately the same rotation angle as the irradiated light.

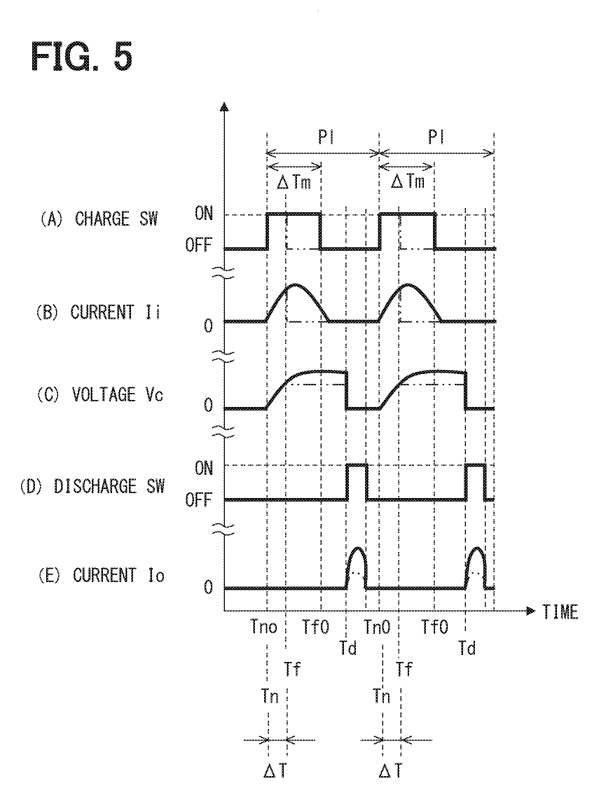

The scanning motor 35 is, for example, a voice coil motor, a direct current motor with brushes, a stepping motor, or the like. The scanning motor 35 drives the scanning mirror 32 to rotate (i.e., swing) within the finite driving range under the control of the control module 51. At this time, the rotation angle of the scanning mirror 32 is changed sequentially in synchronization with the light-emitting period P1 (see FIG. 5 described later) of the light-emitting unit 1 of the light-projecting module 21.

The light-receiving module 41 is arranged offset in the Y-axis direction relative to the light-projecting module 21. The light-receiving module 41 includes a light-receiving lens system 42 and a light-receiving unit 45. The light-receiving lens system 42 exerts an optical effect so as to form an image of the light reflected from the sensing area As on the light-receiving unit 45. The light-receiving lens system 42 forms a light-receiving optical axis along the Z axis. The light-receiving lens system 42 has at least one light-receiving lens 43 on the light-receiving optical axis, which has a lens shape depending on the optical effect to be exerted. The reflected light incident on the reflecting surface 33 of the scanning mirror 32 is guided along the light-receiving optical axis of the light-receiving lens system 42 regardless of the rotation angle of the scanning mirror 32 within the driving range.

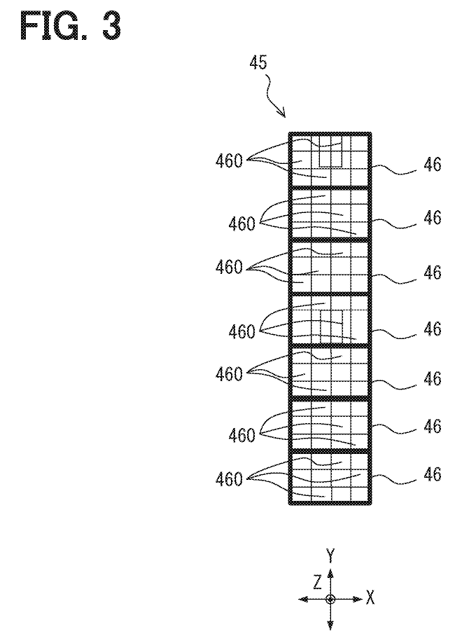

The light-receiving unit 45 is positioned on the light-receiving optical axis of the light-receiving lens system 42. As shown in FIG. 3, the light-receiving unit 45 is constructed by arranging a plurality of light-receiving pixels 46 in an array on the substrate. Each of the light-receiving pixels 46 is further constructed from a plurality of light-receiving elements 460. The light-receiving elements 460 of each light-receiving pixel 46 are formed mainly of a photodiode such as a single photon avalanche diode (SPAD), for example. With this configuration, each light-receiving pixel 46 receives reflected light incident from the light-receiving lens system 42 at each light-receiving element 460.

As shown in FIG. 1, the light-receiving unit 45 has an output circuit 48 integrated therein. The output circuit 48 executes sampling processing under control of the control module 51 for each scanning line associated with the rotation angle of the scanning mirror 32 according to the light-emitting period Pl. Therefore, the output circuit 48 generates light-receiving data for each scanning line based on the output signals from the light-receiving pixels 46 of the light-receiving unit 45 through sampling processing. The light-receiving data thus generated is output from the output circuit 48 to the control module 51.

The control module 51 is mainly composed of at least one computer having a processor 52 and a memory 53. The control module 51 may be entirely housed inside the housing 11 (example of FIG. 1). The control module 51 may be located entirely in the vehicle 5 outside the housing 11. The control module 51 may be distributed across the interior of the housing 11 and the exterior of the vehicle 5.

The control module 51 is connected to the light-emitting unit 1, the scanning motor 35, and the output circuit 48. The control module 51 controls these connected objects by executing a control program stored in the memory 53 using the processor 52. Specifically, the control module 51 controls the light emission of each light-emitting diode 22 in the light-emitting unit 1 and the rotation of the scanning mirror 32 by the scanning motor 35 in synchronization with each light-emitting period P1. In parallel with this control, the control module 51 acquires light-receiving data from the output circuit 48 for each scanning line, which corresponds to each light-emitting period Pl, thereby sensing at least the reflection point distance from the optical sensor 2 to the target and generating sensing information based on the light-receiving data.

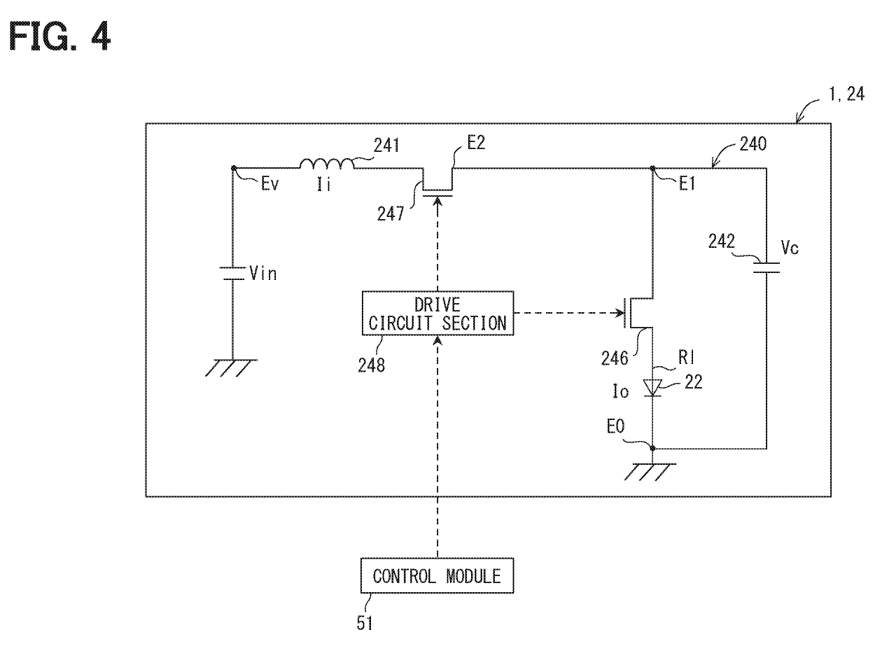

Next, the detailed configuration of the light-emitting unit 1 shown in FIG. 4 will be described. In the light-emitting unit 1, a plurality of light-emitting circuits 24 corresponding to the number of the light-emitting diodes 22 are constructed. In addition to the light-emitting diode 22, the light-emitting circuit 24 includes a resonant circuit section 240, switching elements 246 and 247, and a drive circuit section 248. FIG. 4 shows a representative light-emitting circuit 24 corresponding to one light-emitting diode 22.

The resonant circuit section 240 is provided with a power supply terminal Ev to which a power supply voltage Vin is applied, and a ground terminal E0 to which a ground voltage is applied. The resonant circuit section 240 is a so-called LC series circuit having an inductor 241 and a capacitor 242 connected in series between the power supply terminal Ev and the ground terminal E0. The inductor 241 is mainly composed of an induction coil. The capacitor 242 is mainly composed of a heat-resistant capacitor such as an electrolytic type.

In the light-emitting circuit 24, a section from an intermediate point E1 between the inductor 241 and the capacitor 242 in the resonant circuit section 240 to a ground terminal E0 is connected in parallel with the capacitor 242 by a light-emitting branch path section R1. The light-emitting branch path section Rl is provided with a discharge switching element 246. The discharge switching element 246 is mainly composed of a field effect transistor such as a MOSFET (Metal Oxide Semiconductor Field Effect Transistor). By virtue of this arrangement and configuration in the light-emitting branch path section Rl, the discharge switching element 246 can turn on and off the discharge from the capacitor 242 by switching.

In the light-emitting circuit 24, the light-emitting diode 22 is provided on the light-emitting branch path section R1 from the intermediate point E1 to the ground terminal E0 closer to the ground terminal E0 than the discharge switching element 246. A forward direction in which the light-emitting diode 22 rectifies the current Io is set to a direction from the discharge switching element 246 side toward the ground terminal E0 side. The light-emitting diode 22 emits light by discharging the capacitor 242 in response to the discharge switching element 246 being turned on, thereby generating irradiated light.

In the light-emitting circuit 24, a charge switching element 247 is provided at another intermediate point E2, which is closer to the inductor 241 than the intermediate point E1, which is a branch point where the light-emitting branch path section Rl branches off from between the inductor 241 and the capacitor 242 in the resonant circuit section 240. The charge switching element 247 is mainly composed of a field effect transistor such as a MOSFET. By virtue of this arrangement and configuration at the intermediate point E2, the charge switching element 247 can turn on and off the charge to the capacitor 242 by switching.

In the light-emitting circuit 24, a drive circuit section 248 is connected to each of the switching elements 246 and 247. The drive circuit section 248 is also connected to the control module 51. The drive circuit section 248 drives the switching elements 246 and 247 to turn on and off individually as shown in FIGS. 5 to 7. That is, the switching of each of the switching elements 246 and 247 is controlled by the on/off driving function of the drive circuit section 248.

As shown by the solid and dashed line graphs in each of the sub-figures(A) of FIGS. 5 to 7, in the drive circuit section 248, a reference ON-timing Tn0 for switching the charge switching element 247 from an off drive state to an on drive state is set to match the initial timing of each light-emitting period Pl. At the same time, in the drive circuit section 248, a reference OFF-timing Tf0 for switching the charge switching element 247 from the on drive state to the off drive state is set to a timing a certain period ΔTm after the reference ON-timing Tn0 for each light-emitting period Pl. By setting the cycles of the reference ON-timing Tn0 and the reference OFF-timing Tf0 in this way, the maximum ON period ΔTm of the charge switching element 247 is controlled to be substantially equal to the time constant of the resonant circuit section 240.

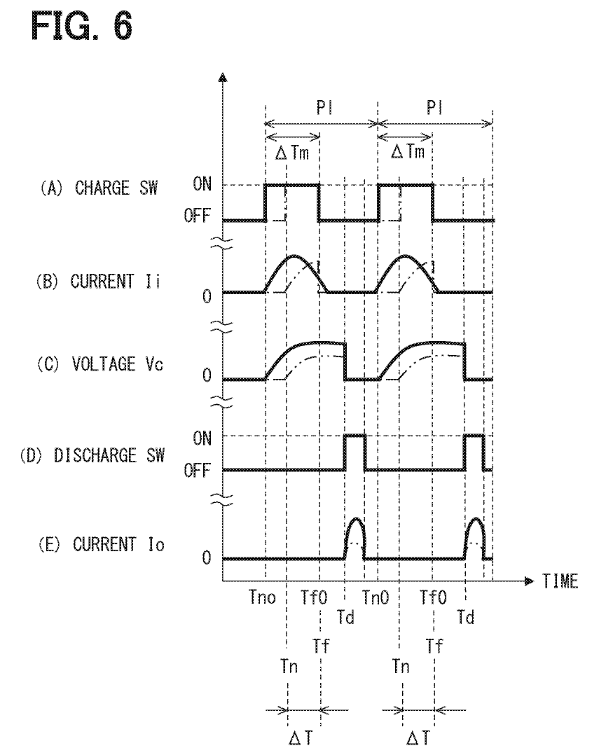

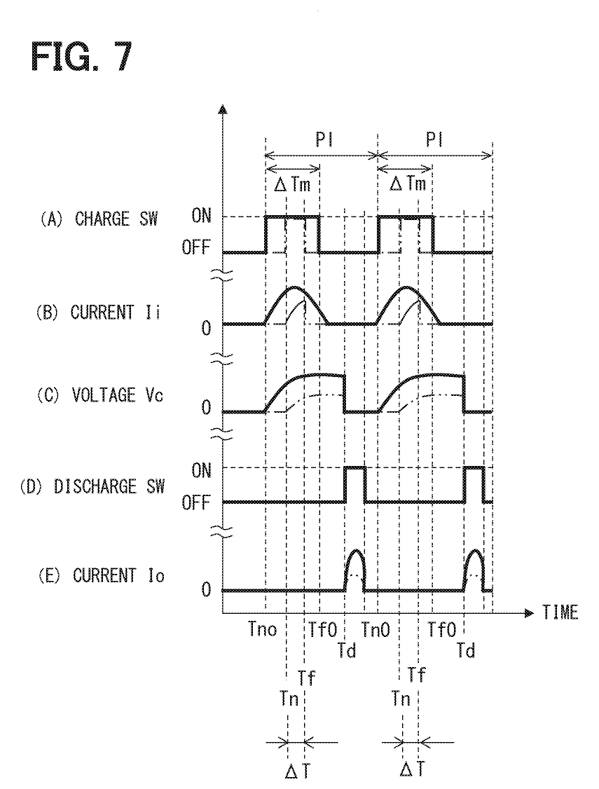

In the drive circuit section 248, the ON-period ΔT of the charge switching element 247 is controlled to a time equal to or less than the maximum ON-period ΔTm for each light-emitting period Pl. At this time, for the charge switching element 247, as shown by the two-dot chain line graph in FIG. 5(A), while the ON-timing Tn is adjusted to match the reference ON-timing Tn0, the OFF-timing Tf may be adjusted to a variable timing before the reference OFF-timing Tf0. For the charge switching element 247, as shown by the two-dot chain line graph in FIG. 6(A), while the OFF-timing Tf is adjusted to match the reference OFF-timing Tf0, the ON-timing Tn may be adjusted to a variable timing after the reference ON-timing Tn0. For the charge switching element 247, as shown by the two-dot chain line graph in FIG. 7(A), the ON-timing Tn may be adjusted to a variable timing after the reference ON-timing Tn0, and the OFF-timing Tf may be adjusted to a variable timing that is later than the ON-timing Tn but before the reference OFF-timing Tf0.

In this way, as shown by the solid line graph and the two-dot chain line graph in each sub-FIGURE(B) of FIGS. 5 to 7, which correspond to the other sub-figures, the more the drive circuit section 248 controls to shorten the ON-period ΔT of the charge switching element 247, the more the time during which current Ii (see also FIG. 4) flows through the inductor 241 in the resonant circuit section 240 decreases. Accordingly, in the resonant circuit section 240, the voltage Vc (see also FIG. 4) charged to the capacitor 242 decreases, as shown by the solid line graph and the dashed-dot line graph corresponding to the other sub-figures in each of the sub-figures (C) in FIGS. 5 to 7. That is, the more the drive circuit section 248 controls the ON period ΔT of the charge switching element 247 to be shortened, the more the charge voltage Vc of the capacitor 242 decreases.

Therefore, as shown by the solid line graphs in each of the sub-figures(D) of FIGS. 5 to 7, in the drive circuit section 248, the discharge switching element 246, which is in the off-drive state, is driven on at a timing later than the reference OFF-timing Tf0 of the charge switching element 247 for each light-emitting period Pl. In other words, the control of the ON period ΔT during which the charge switching element 247 is driven ON precedes the ON timing Td at which the discharge switching element 246 is switched from an off state to an on state for each light-emitting period Pl.

In response to the ON driving of the discharge switching element 246, in the light-emitting branch path section Rl, the discharge current discharged from the capacitor 242, which is in the charge voltage Vc state, flows in through the resonant circuit section 240. As a result, a current Io (see also FIG. 4) that rises and falls in accordance with the charge voltage Vc flows through the light-emitting diode 22, and the light-emitting diode 22 emits light with a peak intensity that follows the rise and fall of the current Io, as shown by the solid line graphs and dashed-dot line graphs corresponding to the each of sub-figures(E) of FIGS. 5 to 7.

Therefore, when the control module 51 recognizes an intensity saturation state, for example, where the received light intensity from a nearby target or a highly reflective target exceeds the upper limit intensity at the light-receiving unit 45, based on the received light data from the output circuit 48, the control module 51 issues a shortening control command to the drive circuit section 248. As a result, the drive circuit section 248 controls the on/off driving of the charge switching element 247 so that the ON-period ΔT is shorter than the maximum ON-period ΔTm in accordance with the degree to which the received light intensity exceeds the upper limit intensity.

On the other hand, when the control module 51 recognizes an insufficient intensity state, for example, where the received light intensity of reflected light from a distant target falls below the lower limit intensity that ensures sensing accuracy in the light-receiving unit 45, based on the received light data from the output circuit 48, the control module 51 issues an extension control command to the drive circuit section 248. As a result, the drive circuit section 248 controls the on/off driving of the charge switching element 247 so as to increase the ON-period ΔT within the range up to the maximum ON-period ΔTm in accordance with the degree of insufficiency of the received light intensity from the lower limit intensity.

### Effects:

The operation and effects in the present embodiment described above will be explained below.

According to the present embodiment, the light-emitting branch path section R1 that branches off between the inductor 241 and the capacitor 242 in the resonant circuit section 240 is provided with a light-emitting diode 22 that generates irradiated light by emitting light, and a discharge switching element 246 that turns on and off the discharge from the capacitor 242 by switching. Therefore, in particular, a charge switching element 247 that switches on and off the charging of the capacitor 242 is provided on the inductor 241 side of the branch point of the light-emitting branch path section Rl in the resonant circuit section 240. According to this configuration, even if the light-receiving intensity of the reflected light relative to the irradiated light becomes saturated, the ON period ΔT of the charge switching element 247 prior to the ON timing Td of the discharge switching element 246 can be shortened, thereby relatively reducing the light-receiving sensitivity. Therefore, by such shortening control, the peak intensity of the irradiated light can be suppressed to a low intensity that matches the received reflected light, thereby ensuring the accuracy of sensing the target.

According to the present embodiment, the OFF timing Tf of the charge switching element 247, which is turned on prior to the ON timing Td of the discharge switching element 246, may be adjusted to be before the periodically set reference OFF timing Tf0, thereby controlling the ON period ΔT of the charge switching element 247. In this case, when the receiving light intensity of the reflected light becomes saturated, the ON period ΔT of the charge switching element 247 can be stably shortened by adjusting the OFF timing Tf of the charge switching element 247 to be earlier than the reference OFF timing Tf0. This is because, by advancing the OFF-timing Tf of the charge switching element 247 relative to the ON-timing Td of the discharge switching element 246, the noise component generated during the off-driving of the charge switching element 247 can be reduced in its effect on the current Io (see FIGS. 4, 5, and 7) flowing through the light-emitting diode 22 during the ON-driving of the discharge switching element 246. Therefore, by such shortening control, it is possible to accurately stabilize the peak intensity of the irradiated light at a low intensity that matches the received reflected light, thereby ensuring sensing accuracy.

According to the present embodiment, the ON-timing Tn of the charge switching element 247, which is turned on prior to the ON-timing Td of the discharge switching element 246, may be adjusted to be after the periodically set reference ON-timing Tn0, thereby controlling the ON-period ΔT of the charge switching element 247. In this case, when the received light intensity of the reflected light becomes saturated, the ON-period ΔT of the charge switching element 247 can be shortened by adjusting the ON-timing Tn of the charge switching element 247 to be later than the reference ON-timing Tn0. Therefore, by such shortening control, it is possible to accurately suppress the peak intensity of the irradiated light to a low intensity that matches the received reflected light, thereby improving sensing accuracy.

According to the present embodiment, the maximum ON-period ΔTm of the charge switching element 247 is controlled by the time constant of the resonant circuit section 240. According to this configuration, even if the received light intensity of the reflected light becomes insufficient as opposed to saturation, the peak intensity of the irradiated light can be increased to the maximum intensity according to the time constant in the resonant circuit section 240 so as to match the received reflected light, thereby making it possible to improve sensing accuracy.

### Other Embodiments:

Although one embodiment has been described above, the present disclosure is not to be construed as being limited to the embodiment of the description, and can be applied to various embodiments within the scope not departing from the spirit of the present disclosure.

In a modified example, the vehicle 5 to which the optical sensor 2 including the light-emitting unit 1 is applied may be, for example, an autonomous robot capable of transporting luggage or collecting information by autonomous driving or remote driving. In a modified example, the object to which the optical sensor 2 including the light-emitting unit 1 is applied may be, for example, a moving object other than the vehicle 5 or a stationary object such as a structure.

What is claimed is:

1. A light-emitting unit that provides an irradiated light by emitting light in an optical sensor, which senses a target object by receiving, with a light-receiving unit, reflected light from the target object in response to the irradiated light irradiated onto a sensing area, comprising:
a resonant circuit section having an inductor and a capacitor;
a light-emitting branch path section branching from between the inductor and the capacitor in the resonant circuit section;
a light-emitting diode provided in the light-emitting branch path section and generating the irradiated light by emitting light;
a discharge switching element provided in the light-emitting branch path section for switching on and off discharge from the capacitor;
a charge switching element that is provided in the resonant circuit section on an inductor side of a branch point of the light-emitting branch path section and that switches on and off charging of the capacitor; and
a drive circuit section that controls the discharge switching element and the charge switching element by individual on/off driving, wherein
prior to an ON-timing of the discharge switching element, a fixed period between a reference ON-timing and a reference OFF-timing, which are periodically set for the charge switching element is defined as a maximum ON-period, and the drive circuit section that controls an ON-period of the charge switching element shortens the ON-period of the charge switching element relative to the maximum ON-period, in accordance with a degree by which a received intensity of the reflected light at the light-receiving unit exceeds an upper limit intensity, and
the drive circuit section increases the ON-period of the charge switching element, within a range up to the maximum ON-period, in accordance with the degree by which the received intensity of the reflected light at the light-receiving unit falls below a lower limit intensity.

2. The light-emitting unit according to claim 1, wherein
the drive circuit section controls the ON-period of the charge switching element by adjusting the OFF-timing of the charge switching element, which is turned on prior to the ON-timing of the discharge switching element, to be before the reference OFF-timing, which is periodically set.

3. The light-emitting unit according to claim 1, wherein
the drive circuit section controls the ON-period of the charge switching element by adjusting the ON-timing of the charge switching element, which is turned on prior to the ON-timing of the discharge switching element, to a timing after the reference OFF-timing, which is periodically set.

4. The light-emitting unit according to claim 1, wherein
the drive circuit controls the maximum ON-period of the charge switching element to a time constant of the resonant circuit section.

5. An optical sensor, comprising:
the light-emitting unit according to claim 1; and
a light-receiving unit that receives the reflected light in response to the irradiated light emitted by the light-emitting unit.

6. A light-emitting unit that provides an irradiated light by emitting light in an optical sensor, which senses a target object by receiving, with a light-receiving unit, reflected light from the target object in response to the irradiated light irradiated onto a sensing area, comprising:
a resonant circuit section having an inductor and a capacitor;
a light-emitting branch path section branching from between the inductor and the capacitor in the resonant circuit section;
a light-emitting diode provided in the light-emitting branch path section and generating the irradiated light by emitting light;
a discharge switching element provided in the light-emitting branch path section for switching on and off discharge from the capacitor;
a charge switching element that is provided in the resonant circuit section on an inductor side of a branch point of the light-emitting branch path section and that switches on and off charging of the capacitor; and
a processor with a memory storing computer program code executable by the processor, the processor configured to cause the light-emitting unit to:
control the discharge switching element and the charge switching element by individual on/off driving,
when a fixed period between a reference ON-timing and a reference OFF-timing, which are periodically set for the charge switching element is defined as a maximum ON-period, prior to an ON-timing of the discharge switching element, control an ON-period of the charge switching element shortens the ON-period of the charge switching element relative to the maximum ON-period, in accordance with a degree by which a received intensity of the reflected light at the light-receiving unit exceeds an upper limit intensity, and
increase the ON-period of the charge switching element, within a range up to the maximum ON-period, in accordance with the degree by which the received intensity of the reflected light at the light-receiving unit falls below a lower limit intensity.

7. The light-emitting unit according to claim 6, wherein
the processor is further configured to cause the power conversion device to
control the ON-period of the charge switching element by adjusting the OFF-timing of the charge switching element, which is turned on prior to the ON-timing of the discharge switching element, to be before the reference OFF-timing, which is periodically set.

8. The light-emitting unit according to claim 6, wherein
the processor is further configured to cause the power conversion device to
control the ON-period of the charge switching element by adjusting the ON-timing of the charge switching element, which is turned on prior to the ON-timing of the discharge switching element, to a timing after the reference OFF-timing, which is periodically set.

9. The light-emitting unit according to claim 6, wherein
the processor is further configured to cause the power conversion device to
control the maximum ON-period of the charge switching element to a time constant of the resonant circuit section.
